(19) United States
(12) Patent Application Publication
(10) Pub. No.: US 2017/0154953 A1
(43) Pub. Date: Jun. 1, 2017

(54) SILICON CARBIDE SEMICONDUCTOR DEVICE AND METHOD OF MANUFACTURING THE SAME

(71) Applicant: Sumitomo Electric Industries, Ltd., Osaka-shi (JP)

(72) Inventors: Keiji Wada, Osaka-shi (JP); Ryosuke Kubota, Osaka-shi (JP); Toru Hiyoshi, Osaka-shi (JP)

(21) Appl. No.: 15/320,220

(22) PCT Filed: May 8, 2015
(86) PCT No.: PCT/JP2015/063328

§ 371 Date: Dec. 19, 2016

(30) Foreign Application Priority Data
Jun. 23, 2014 (JP) 2014-128213

(51) Int. Cl. H01L 29/06; H01L 21/265; H01L 21/02; H01L 29/16

(52) U.S. Cl. CPC H01L 29/063; H01L 29/1608; H01L 21/26513; H01L 21/02529

(57) ABSTRACT

A silicon carbide semiconductor device includes an impurity region including a p type impurity and disposed within a silicon carbide layer to surround an element region as seen in plan view. The impurity region has a peak concentration of the p type impurity at a position within the silicon carbide layer distant from a first main surface. The peak concentration is not less than 1×10¹⁶ cm⁻³ and not more than 5×10¹⁷ cm⁻³. The impurity region is formed by implanting ions of the p type impurity into the silicon carbide layer. Then, a silicon dioxide film is formed to cover the first main surface of the silicon carbide layer by performing a thermal oxidation process on the silicon carbide layer, and the concentration of the p type impurity in the vicinity of the first main surface is lowered.

### TECHNICAL FIELD

The present invention relates to silicon carbide semiconductor devices and methods of manufacturing the same. More specifically, the present invention relates to a silicon carbide semiconductor device with improved breakdown voltage characteristics and a method of manufacturing the same.

### BACKGROUND ART

Conventionally, silicon has been widely used as a material for a semiconductor device. In recent years, silicon carbide has been increasingly employed as a material for a semiconductor device.

Silicon carbide is a wide band gap semiconductor having a band gap wider than that of silicon. By employing the silicon carbide as a material for a semiconductor device, a higher breakdown voltage and loss reduction of the semiconductor device can be achieved, and the semiconductor device can be used in a high-temperature environment.

In order to achieve a higher breakdown voltage of a semiconductor device, studies have been conducted on the structure of a semiconductor device in addition to the material of a semiconductor device. By way of example, studies have been conducted on an outer peripheral structure (also referred to as a termination structure) surrounding the outer periphery of an element region in a silicon carbide semiconductor device. When a high voltage is applied to a silicon carbide semiconductor device, the outer peripheral structure performs the function of relaxing electric field concentration. The relaxed electric field concentration can lead to a higher breakdown voltage of the silicon carbide semiconductor device.

To date, various proposals on the outer peripheral structure of a silicon carbide semiconductor device have been described in documents. For example, Japanese Patent Laying-Open No. 2003-101039 (PTD 1) discloses a high-breakdown-voltage semiconductor device including a RESURF (Reduced Surface Field) layer and two guard ring layers. One of the two guard ring layers is formed in the RESURF layer and has a high impurity concentration. The other guard ring layer is disposed outside the RESURF layer and has an impurity concentration substantially equal to that in the RESURF layer.

For example, Japanese Patent Laying-Open No. 2008-270412 (PTD 2) discloses a silicon carbide semiconductor device including a RESURF layer and an electric field relaxing layer. The electric field relaxing layer is separated from the RESURF layer and disposed on the inner peripheral side of the RESURF layer.

For example, NPD 1 discloses a Schottky barrier diode as one type of silicon carbide semiconductor devices. This Schottky barrier diode has a termination structure. The termination structure has, for example, a JTE (Junction Termination Extension) region and a RESURF region. NPD 1 also discloses relation between an impurity concentration in the JTE region and a breakdown voltage of the Schottky barrier diode.

For example, NPD 2 and NPD 3 each propose a structure of and concentration in the JTE region described above.

### CITATION LIST

### Patent Documents

PTD 1: Japanese Patent Laying-Open No. 2003-101039
PTD 2: Japanese Patent Laying-Open No. 2008-270412

### Non Patent Documents

NPD 1: Hiroyuki Matsunami, Noboru Otani, Tsunenobu Kimoto, and Takashi Nakamura, “Semiconductor SiC Technology and Application,” second edition, Nikkan Kogyo Shimbun, Ltd., Sep. 30, 2011, p. 341 and p. 353
NPD 2: Hiroki Niwa, Gan Feng, Jun Suda, and Tsunenobu Kimoto, “Breakdown Characteristics of 12-20 kV-class 4H-SiC PiN Diodes with Improved Junction Termination Structures,” Proceedings of the 2012 24th International Symposium on Power Semiconductor Devices and ICs, 3-7 Jun. 2012, Bruges, Belgium, p 381-384 NPD 3: Hiroki Niwa, Jun Suda, and Tsunenobu Kimoto, “21.7 kV 4H-SiC PiN Diode with a Space-Modulated Junction Termination Extension,” The Japan Society of Applied Physics, Applied Physics Express 5 (2012) 64001, 64001-1-64001-3

### SUMMARY OF INVENTION

### Technical Problem

The documents cited above describe, with regard to a termination structure such as a JTE region or RESURF region, the effect of a specific configuration or impurity concentration on the breakdown voltage of a silicon carbide semiconductor device. However, the above documents fail to describe in detail a concentration profile of an impurity along a depth direction with regard to these regions.

When avalanche breakdown occurs, for example, a reverse current flows through the termination structure (JTE region or RESURF region). By setting an appropriate concentration profile of an impurity in a depth direction of an impurity region, the breakdown resistance of a silicon carbide semiconductor device may be improved.

An object of the present invention is to provide a silicon carbide semiconductor device capable of achieving improved breakdown resistance, and a method of manufacturing the same.

### Solution to Problem

A silicon carbide semiconductor device according to one embodiment of the present invention includes: a silicon carbide layer including a first main surface and a second main surface located opposite the first main surface, and having a first conductivity type; an element region including a semiconductor element portion formed in the silicon carbide layer; and an impurity region having a second conductivity type different from the first conductivity type, and being disposed within the silicon carbide layer to surround the element region as seen in plan view. The impurity region has a peak concentration of an impurity of the second conductivity type at a position within the silicon carbide layer distant from the first main surface of the silicon carbide layer. The peak concentration is not less than 1×10¹⁶ cm⁻³ and not more than 5×10¹⁷ cm⁻³.

A method of manufacturing a silicon carbide semiconductor device according to one embodiment of the present invention includes the steps of: preparing a silicon carbide layer including a first main surface and a second main surface located opposite the first main surface, and having a first conductivity type; forming an impurity region including an impurity having a second conductivity type different from the first conductivity type within the silicon carbide layer, by implanting ions of the impurity into a region of the silicon carbide layer that surrounds an element region where a semiconductor element portion is to be disposed; activating the impurity by heating the silicon carbide layer; and forming a silicon dioxide film to cover the first main surface of the silicon carbide layer by performing thermal oxidation on the silicon carbide layer. The step of forming a silicon dioxide film includes the step of lowering a concentration of the impurity in the vicinity of the first main surface, by causing the impurity to migrate from the first main surface of the silicon carbide layer into the silicon carbide layer.

### Advantageous Effects of Invention

According to the above, a silicon carbide semiconductor device capable of achieving improved breakdown resistance, and a method of manufacturing the same can be provided.

### BRIEF DESCRIPTION OF DRAWINGS

FIG. 1 is a schematic sectional view schematically showing the structure of a silicon carbide semiconductor device according to a first embodiment of the present invention.

FIG. 2 is a schematic plan view schematically showing the structure of a JTE (Junction Termination Extension) region and a guard ring region of the silicon carbide semiconductor device according to one embodiment of the present invention.

FIG. 3 is a schematic diagram showing relation between a position in a Y direction of, and impurity concentration in, the JTE region.

FIG. 4 is a diagram illustrating the position in the Y direction in FIG. 3.

FIG. 5 is a schematic diagram showing the silicon carbide semiconductor device according to the embodiment of the present invention in which avalanche breakdown has occurred.

FIG. 6 is a flowchart schematically illustrating a method of manufacturing the silicon carbide semiconductor device according to one embodiment of the present invention.

FIG. 7 is a schematic sectional view schematically illustrating a step (S10) included in the method of manufacturing the silicon carbide semiconductor device according to one embodiment of the present invention.

FIG. 8 is a schematic sectional view schematically illustrating a step (S20) included in the method of manufacturing the silicon carbide semiconductor device according to one embodiment of the present invention.

FIG. 9 is a schematic sectional view schematically illustrating a step (S40) included in the method of manufacturing the silicon carbide semiconductor device according to one embodiment of the present invention.

FIG. 10 is a schematic diagram showing variation in impurity concentration profile in the JTE region.

FIG. 11 is a schematic diagram showing a position in the Y direction of the guard ring region.

FIG. 12 is a schematic diagram of a concentration profile in a p type impurity concentration region in a second embodiment of the present invention.

### DESCRIPTION OF EMBODIMENTS

### Description of Embodiments of the Present Invention

First, embodiments of the present invention will be described in list form. In the present specification, an individual orientation is represented by [ ], a group orientation is represented by < >, an individual plane is represented by ( ), and a group plane is represented by { }. In addition, a negative crystallographic index is normally expressed by putting “-” (bar) above a numeral, but is expressed by putting a negative sign before the numeral in the present specification. Furthermore, an “oxide film” means a film of silicon dioxide (SiO₂).

(1) A silicon carbide semiconductor device according to one embodiment of the present invention includes: a silicon carbide layer (10) including a first main surface (10a) and a second main surface (10b) located opposite the first main surface (10a), and having a first conductivity type; an element region (IR) including a semiconductor element portion (7) formed in the silicon carbide layer (10); and an impurity region having a second conductivity type different from the first conductivity type, and being disposed within the silicon carbide layer (10) to surround the element region (IR) as seen in plan view. The impurity region has a peak concentration of an impurity of the second conductivity type at a position (P) within the silicon carbide layer (10) distant from the first main surface (10a) of the silicon carbide layer (10). The peak concentration is not less than 1×10¹⁶ cm⁻³ and not more than 5×10¹⁷ cm⁻³.

According to the above configuration, the silicon carbide semiconductor device capable of achieving improved breakdown resistance can be provided. When avalanche breakdown occurs, for example, a reverse current flows through the impurity region. It is considered that the reverse current tends to flow through a portion near the peak of the impurity concentration in the impurity region. Thus, the reverse current tends to flow through a portion distant from the first main surface of the silicon carbide layer. The breakdown resistance of the silicon carbide semiconductor device can be thus improved.

(2) Preferably, the position (P) of the peak concentration is a position of not less than 0.3 μm and not more than 0.5 μm from the first main surface (10a) of the silicon carbide layer (10).

According to the above configuration, the possibility of the reverse current flowing through a path distant from the first main surface (the inside of the impurity region) can be increased.

(3) Preferably, the impurity region is disposed within the silicon carbide layer (10a) to be in contact with the first main surface (10a) of the silicon carbide layer (10).

According to the above configuration, even when the impurity region is in contact with the first main surface, the possibility of the reverse current flowing through a path distant from the first main surface (the inside of the impurity region) can be increased.

(4) Preferably, the impurity region includes a JTE (Junction Termination Extension) region (2).

According to the above configuration, the reverse current can be passed through the inside of the JTE region (location distant from the first main surface).

(5) Preferably, the impurity region includes a guard ring region (3).

According to the above configuration, the reverse current can be passed through the inside of the guard ring region (location distant from the first main surface).

(6) Preferably, the first main surface (10a) of the silicon carbide layer (10) is a surface having an off angle of not less than −8° and not more than 8° relative to a (0001) plane.

According to the above configuration, the impurity of the second conductivity type tends to have a peak concentration at a position within the silicon carbide layer distant from the first main surface.

(7) Preferably, the first conductivity type is n type, and the second conductivity type is p type.

According to the above configuration, the manufacturability of the silicon carbide semiconductor device can be improved.

(8) A method of manufacturing a silicon carbide semiconductor device according to another embodiment of the present invention includes the steps of: preparing a silicon carbide layer (10) including a first main surface (10a) and a second main surface (10b) located opposite the first main surface (10a), and having a first conductivity type (S10); forming an impurity region including an impurity having a second conductivity type different from the first conductivity type within the silicon carbide layer (10), by implanting ions of the impurity into a region of the silicon carbide layer (10) that surrounds an element region (IR) where a semiconductor element portion (7) is to be disposed (S20); activating the impurity by heating the silicon carbide layer (10) (S30); and forming a silicon dioxide film (15c) to cover the first main surface (10a) of the silicon carbide layer (10) by performing thermal oxidation on the silicon carbide layer (10) (S40). The step of forming a silicon dioxide film (S40) includes the step of lowering a concentration of the impurity in the vicinity of the first main surface (10a), by causing the impurity to migrate from the first main surface (10a) of the silicon carbide layer (10) into the silicon carbide layer (10).

According to the above configuration, the silicon carbide semiconductor device capable of achieving improved breakdown resistance can be manufactured. In the step of forming a silicon dioxide film, heat treatment is performed on the silicon carbide layer. This can cause the impurity to migrate from the first main surface into the silicon carbide layer. When avalanche breakdown occurs, for example, a reverse current tends to flow through a portion distant from the first main surface of the silicon carbide layer. The breakdown resistance of the silicon carbide semiconductor device can be thus improved.

(9) Preferably, by the step of forming a silicon dioxide film (S40), the impurity region has a peak concentration of the impurity at a position (P) within the silicon carbide layer (10) distant from the first main surface (10a). The peak concentration is not less than 1×10¹⁶ cm⁻³ and not more than 5×10¹⁷ cm⁻³.

According to the above configuration, the possibility of the reverse current flowing through a path distant from the first main surface (the inside of the impurity region) can be increased.

(10) Preferably, the position (P) of the peak concentration is a position of not less than 0.3 μm and not more than 0.5 μm from the first main surface (10a) of the silicon carbide layer (10).

According to the above configuration, the possibility of the reverse current flowing through a path distant from the first main surface (the inside of the impurity region) can be increased.

(11) Preferably, the impurity region is disposed within the silicon carbide layer (10) to be in contact with the first main surface (10a) of the silicon carbide layer (10).

According to the above configuration, even when the impurity region is in contact with the first main surface, the possibility of the reverse current flowing through a path distant from the first main surface (the inside of the impurity region) can be increased.

(12) Preferably, the impurity region includes a JTE (Junction Termination Extension) region (2).

According to the above configuration, the reverse current can be passed through the inside of the JTE region (location distant from the first main surface).

(13) Preferably, the impurity region includes a guard ring region (3).

According to the above configuration, the reverse current can be passed through the inside of the guard ring region (location distant from the first main surface).

(14) Preferably, the first main surface (10a) of the silicon carbide layer (10) is a surface having an off angle of not less than −8° and not more than 8° relative to a (0001) plane.

According to the above configuration, in the step of forming a silicon dioxide film, heat treatment is performed on the silicon carbide layer, so that the impurity of the second conductivity type tends to have a peak concentration at a position within the silicon carbide layer distant from the first main surface.

(15) Preferably, the step of forming an impurity region includes the step of implanting the ions of the impurity such that the concentration of the impurity decreases as a depth from the first main surface (10a) of the silicon carbide layer (10) increases. The step of forming a silicon dioxide film (S40) includes the step of forming a concentration profile of the impurity, the concentration profile including a portion (PF) where the concentration of the impurity flattens out with respect to a depth direction from the first main surface (10a) of the silicon carbide layer (10).

According to the above configuration, in the impurity region, a portion through which the reverse current flows (current path) increases in width in the depth direction. The current density in the impurity region can be thus lowered. Accordingly, the breakdown resistance of the silicon carbide semiconductor device can be further improved.

(16) Preferably, the first conductivity type is n type, and the second conductivity type is p type.

According to the above configuration, the manufacturability of the silicon carbide semiconductor device can be improved.

### DETAILS OF EMBODIMENTS OF THE PRESENT INVENTION

Embodiments of the present invention will be described below with reference to the drawings. In the following drawings, the same or corresponding parts are designated by the same reference numbers and are not described repeatedly.

### First Embodiment

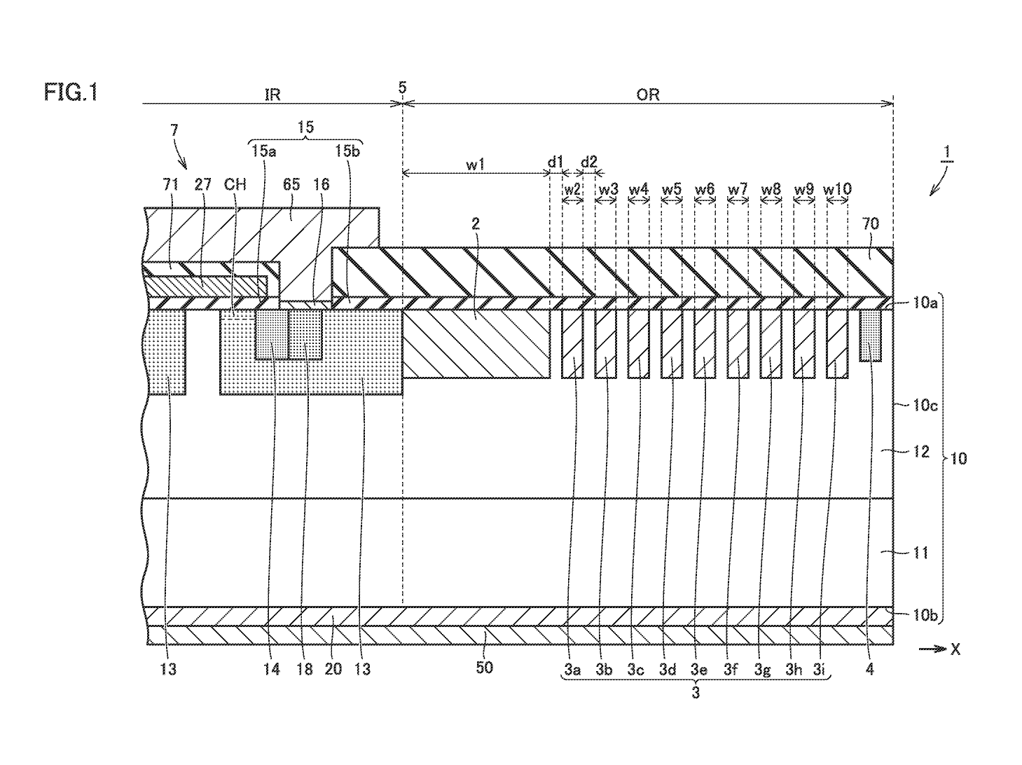

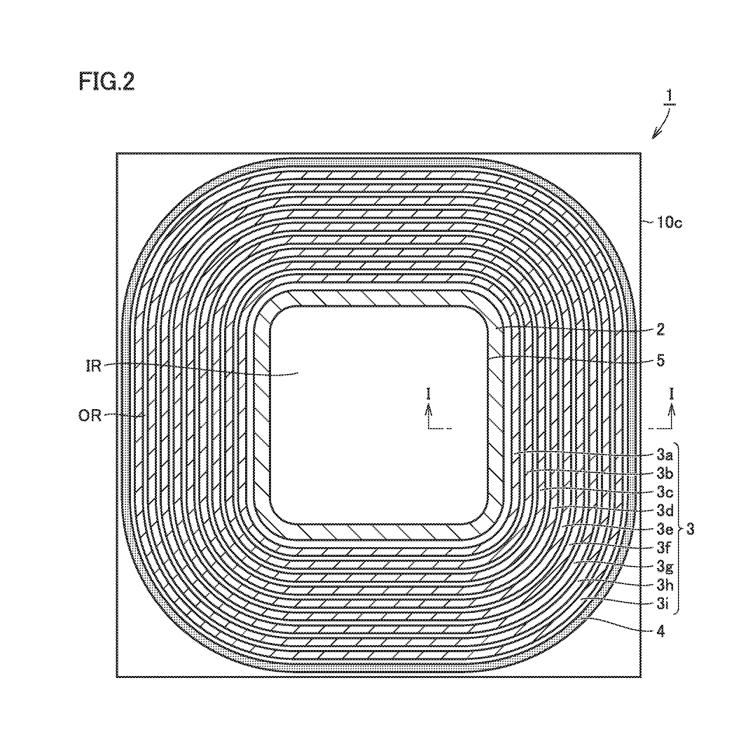

FIG. 1 is a schematic sectional view schematically showing the structure of a silicon carbide semiconductor device according to a first embodiment of the present invention. FIG. 2 is a schematic plan view schematically showing the structure of a JTE (Junction Termination Extension) region and a guard ring region of the silicon carbide semiconductor device according to one embodiment of the present invention.

Referring to FIGS. 1 and 2, the configuration of a MOSFET (Metal Oxide Semiconductor Field Effect Transistor) is described first as the silicon carbide semiconductor device according to one embodiment of the present invention.

Referring to FIGS. 1 and 2, a silicon carbide semiconductor device 1 includes an element region IR and a termination region OR. Termination region OR is disposed outside element region IR and surrounds element region IR. Termination region OR is a region for relaxing electric field concentration in silicon carbide semiconductor device 1.

A detailed configuration of silicon carbide semiconductor device 1 is now described. Silicon carbide semiconductor device 1 includes a silicon carbide layer 10, an insulating film 15, a gate electrode 27, a source electrode 16, a drain electrode 20, an insulating film 70, an interlayer insulating film 71, a pad electrode 65, and a backside surface protecting electrode 50.

Silicon carbide layer 10 is made of hexagonal silicon carbide having a polytype of 4H, for example, and includes a first main surface 10a and a second main surface 10b. Second main surface 10b is located opposite first main surface 10a. Silicon carbide layer 10 has n type conductivity (first conductivity type).

Main surface 10a is a surface having an off angle of not less than −8° and not more than 8° relative to (0001). Thus, main surface 10a may be a (0001) plane.

Silicon carbide layer 10 includes an n⁺ substrate 11 and a drift layer 12. N⁺ substrate 11 is made of hexagonal silicon carbide having a polytype of 4H, for example. N⁺ substrate 11 contains a high concentration of an impurity (donor) such as N (nitrogen). N⁺ substrate 11 has an impurity concentration of approximately 1.0×10¹⁸ cm⁻³, for example.

Drift layer 12 is an epitaxial layer made of hexagonal silicon carbide having a polytype of 4H, for example. Drift layer 12 has a thickness of not less than approximately 5 μm and not more than approximately 35 μm, for example. The term “thickness” or “depth” means the length in a direction perpendicular to first main surface 10a of silicon carbide layer 10.

An impurity concentration in drift layer 12 is lower than the impurity concentration in n⁺ substrate 11. Drift layer 12 has an impurity concentration of not less than approximately 1.0×10¹⁵ cm⁻³ and not more than approximately 1.0×10¹⁶ cm⁻³, for example. Drift layer 12 contains an impurity such as nitrogen.

Silicon carbide layer 10 is formed of two layers in this embodiment. However, silicon carbide layer 10 may be implemented with a single layer. Alternatively, silicon carbide layer 10 may be formed of three or more layers.

Element region IR includes a semiconductor element portion 7 formed in silicon carbide layer 10. More specifically, element region IR includes body regions 13, source regions 14, and p⁺ regions 18. Termination region OR includes a JTE region 2, a guard ring region 3, and a field stop region 4. Body regions 13, source regions 14, p⁺ regions 18, JTE region 2, guard ring region 3, and field stop region 4 are disposed within silicon carbide layer 10.

JTE region 2 is a first electric field relaxing region for relaxing electric field concentration in silicon carbide semiconductor device 1. As shown in FIG. 1, as seen in plan view, JTE region 2 is disposed outside body region 13, and disposed within silicon carbide layer 10 to surround body region 13. The term “as seen in plan view” means a view seen from first main surface 10a of silicon carbide layer 10.

JTE region 2 is in contact with body region 13. A boundary 5 between JTE region 2 and body region 13 corresponds to the boundary between element region IR and termination region OR. Furthermore, JTE region 2 is in contact with first main surface 10a of silicon carbide layer 10.

JTE region 2 has a second conductivity type different from the first conductivity type. JTE region 2 has p type conductivity in this embodiment. JTE region 2 contains an impurity (acceptor) such as Al (aluminum), B (boron). A dose amount of the impurity contained in JTE region 2 is not less than 1×10¹³ cm⁻². Preferably, the dose amount of the impurity contained in JTE region 2 is within the range of not less than 1×10¹³ cm⁻² and not more than 2×10¹³ cm⁻². The dose amount can be determined by, for example, integrating the p type impurity concentration in JTE region 2 along a depth direction of JTE region 2.

A direction X shown in FIG. 2 represents a direction from a central portion (element region IR) of first main surface 10a of silicon carbide layer 10 toward a peripheral portion (termination region OR) of first main surface 10a. Direction X is herein also referred to as a “peripheral direction.”

A length along the peripheral direction, that is, a length along direction X, is herein referred to as a “width.” A width w1 of JTE region 2 is not less than 15 μm and not more than 50 μm. The thickness of JTE region 2 with reference to first main surface 10a is not less than approximately 0.3 μm and not more than approximately 0.8 μm, for example.

Guard ring region 3 is a second electric field relaxing region for relaxing electric field concentration in silicon carbide semiconductor device 1. Specifically, guard ring region 3 is a p type region containing an impurity such as aluminum or boron. A dose amount of the impurity contained in guard ring region 3 is not less than 1×10¹³ cm⁻², for example. The dose amount of the impurity contained in guard ring region 3 may be substantially equal to the dose amount of the impurity contained in JTE region 2 (for example, within the range of ±5% with reference to the dose amount of the impurity contained in JTE region 2).

The electric field concentration in silicon carbide semiconductor device 1 can be relaxed by JTE region 2 as well as guard ring region 3. Thus, a breakdown voltage of silicon carbide semiconductor device 1 can be further increased. For this reason, it is preferable to provide guard ring region 3 in silicon carbide semiconductor device 1. If a breakdown voltage required of silicon carbide semiconductor device 1 can be achieved by JTE region 2, however, guard ring region 3 does not need to be provided in silicon carbide semiconductor device 1 according to the embodiment of the present invention.

Guard ring region 3 may have a plurality of guard ring portions 3a to 3i. As shown in FIG. 2, as seen in plan view, the plurality of guard ring portions 3a to 3i each have an annular shape, and are disposed at a distance from one another. In one embodiment, there are nine guard ring portions. However, the number of guard ring portions is not particularly limited. Furthermore, in the configuration shown in FIG. 1, each guard ring portion is in contact with first main surface 10a of silicon carbide layer 10. However, each guard ring portion may be disposed within silicon carbide layer 10 (drift layer 12) at a distance from first main surface 10a of silicon carbide layer 10.

Field stop region 4 is disposed outside guard ring region 3 and surrounds guard ring region 3 as seen in plan view. The “outside” corresponds to the side of an end 10c of silicon carbide layer 10. Field stop region 4 is provided separately from guard ring region 3. Field stop region 4 has n type conductivity. An impurity concentration in field stop region 4 is higher than the impurity concentration in drift layer 12. Field stop region 4 contains an impurity such as P (phosphorus).

Body region 13 is a p type region. Body region 13 contains an impurity (acceptor) such as aluminum, boron. In one embodiment, body region 13 is disposed within silicon carbide layer 10 to be in contact with first main surface 10a of silicon carbide layer 10.

An impurity concentration in body region 13 is higher than the impurity concentration in JTE region 2. In other words, the impurity concentration in JTE region 2 is lower than the impurity concentration in body region 13. For example, the impurity concentration in body region 13 in the vicinity of first main surface 10a is not less than approximately 1×10¹⁶ cm⁻³ and not more than approximately 5×10¹⁷ cm⁻³. The impurity concentration in a deep portion of body region 13 is approximately 1×10¹⁸ cm⁻³, for example. The thickness of body region 13 with reference to first main surface 10a of silicon carbide layer 10 is not less than approximately 0.5 μm and not more than approximately 1.0 μm, for example.

Source region 14 is an n type region. Source region 14 is disposed within body region 13 and is in contact with first main surface 10a of silicon carbide layer 10. Source region 14 is separated from drift layer 12 by body region 13.

Source region 14 contains an impurity such as P (phosphorus). An impurity concentration in source region 14 is higher than the impurity concentration in drift layer 12. For example, source region 14 has an impurity concentration of not less than approximately 1×10¹⁹ cm⁻³ and not more than approximately 1×10²⁰ cm⁻³.

P⁺ region 18 (contact region) is a p type region and contains an impurity such as aluminum or boron. P⁺ region 18 is disposed within body region 13 and is in contact with first main surface 10a of silicon carbide layer 10. As shown in FIG. 1, p⁺ region 18 may be in contact with source region 14. An impurity concentration in p⁺ region 18 is higher than the impurity concentration in body region 13. For example, p⁺ region 18 has an impurity concentration of not less than approximately 2×10¹⁹ cm⁻³ and not more than approximately 5×10²⁰ cm⁻³.

Insulating film 15 includes a gate insulating film 15a and an insulating film 15b. In this embodiment, insulating film 15 (gate insulating film 15a and insulating film 15b) is a silicon dioxide film, for example, a thermal oxidation film. The thickness of gate insulating film 15a and insulating film 15b with reference to first main surface 10a is approximately 50 nm, for example.

Gate insulating film 15a is provided on first main surface 10a of silicon carbide layer 10, in a position facing channel regions CH formed in body regions 13. Gate insulating film 15a is in contact with body regions 13, source regions 14 and drift layer 12 to extend from an upper surface of one of source regions 14 to an upper surface of the other source region 14. Insulating film 15b is disposed on first main surface 10a of silicon carbide layer 10 to be in contact with JTE region 2.

Gate electrode 27 is disposed on gate insulating film 15a. Gate electrode 27 extends from above one of source regions 14 to above the other source region 14 to face a portion of drift layer 12 lying between these two source regions, and two channel regions CH. Gate electrode 27 is made of a conductor such as polysilicon doped with an impurity, or aluminum.

Source electrode 16 is in contact with and electrically connected to source region 14 and p⁺ region 18. Preferably, source electrode 16 is in ohmic contact with source region 14 and p⁺ region 18. In one embodiment, source electrode 16 is made of a material including nickel and silicon. Source electrode 16 may be made of a material including titanium, aluminum and silicon.

Insulating film 70 is disposed in contact with insulating film 15b. Interlayer insulating film 71 is disposed on gate insulating film 15a to cover gate electrode 27. Each of insulating film 70 and interlayer insulating film 71 is a silicon dioxide film, for example. A deposited oxide film, for example, is applied to each of insulating film 70 and interlayer insulating film 71.

A sum of the thickness of insulating film 70 and the thickness of insulating film 15b may be not less than approximately 0.05 μm and not more than approximately 2.0 μm, for example. Accordingly, insulating film 70 may be omitted from the configuration shown in FIG. 1. Alternatively, an additional insulating film (for example, a silicon nitride film) may be provided on insulating film 70.

Drain electrode 20 is in contact with second main surface 10b of silicon carbide layer 10 and electrically connected to n⁺ substrate 11. Drain electrode 20 may have a configuration similar to that of source electrode 16 described above, for example. Alternatively, drain electrode 20 may be made of another material capable of making ohmic contact with n⁺ substrate 11, such as nickel.

Backside surface protecting electrode 50 is in contact with drain electrode 20. Backside surface protecting electrode 50 is thus electrically connected to drain electrode 20. Backside surface protecting electrode 50 is made of titanium, nickel, silver, or an alloy thereof, for example.

Pad electrode 65 overlies insulating film 70 and interlayer insulating film 71 and is in contact with source electrode 16. Pad electrode 65 is thus electrically connected to source region 14 and p⁺ region 18 with source electrode 16 interposed therebetween. Pad electrode 65 may be made of aluminum, for example. In addition, pad electrode 65 may be partially disposed on the insulating film (insulating film 70 and insulating film 15b) to span the boundary between JTE region 2 and body region 13.

In this embodiment, width w1 of JTE region 2 is not less than 15 μm and not more than 50 μm. When width w1 is less than 15 μm, the size of silicon carbide semiconductor device 1 can be reduced. However, the effect of relaxing electric field concentration tends to be reduced in JTE region 2. When width w1 of JTE region 2 exceeds 50 μm, on the other hand, the effect of relaxing electric field concentration can be exercised sufficiently in JTE region 2. However, the size of silicon carbide semiconductor device 1 increases. In order to sufficiently increase the breakdown voltage of silicon carbide semiconductor device 1 while minimizing the increase in size of silicon carbide semiconductor device 1, therefore, width w1 of JTE region 2 is preferably not less than 15 μm and not more than 50 μm.

The dose amount of the impurity contained in JTE region 2 is preferably within the range of not less than 1×10¹³ cm⁻² and not more than 2×10¹³ cm⁻². When the dose amount of the impurity in JTE region 2 is less than 1×10¹³ cm⁻², it is believed, for example, that the breakdown voltage of silicon carbide semiconductor device 1 will not be sufficiently increased. When the dose amount of the impurity in JTE region 2 exceeds 2×10¹³ cm⁻², on the other hand, the effect of relaxing electric field concentration by JTE region 2 tends to be reduced. Therefore, the dose amount of the impurity in JTE region 2 is preferably within the range of not less than 1×10¹³ cm⁻² and not more than 2×10¹³ cm⁻².

In guard ring region 3, each of widths w2 to w10 between nine guard ring portions 3a to 3i is 5 μm, for example. A distance d1 between JTE region 2 and guard ring region 3 is not less than approximately 2 μm and not more than approximately 5 μm, for example. A distance d2 between two adjacent guard ring portions is not less than approximately 2 μm and not more than approximately 5 μm, for example. For example, a width from the end of JTE region 2 (the boundary between JTE region 2 and body region 13) to the end of the outermost guard ring portion (guard ring portion 3i in the configuration shown in FIG. 2) is not less than approximately 20 μm and not more than approximately 200 μm.

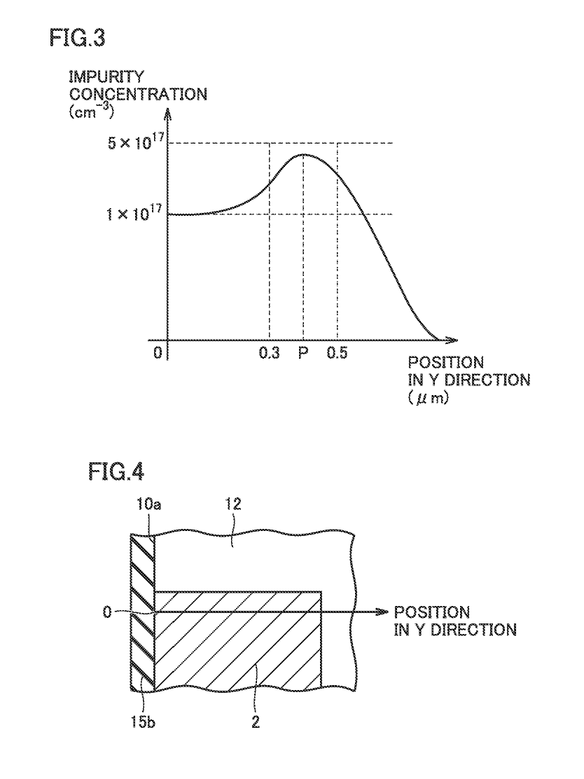

Referring to FIGS. 3 and 4, relation between the impurity concentration in, and a position in a Y direction of, JTE region 2 is described. As shown in FIG. 4, the Y direction is the direction of the normal to first main surface 10a of silicon carbide layer 10, in other words, the depth direction. With first main surface 10a as a position 0, a direction from first main surface 10a toward second main surface 10b is a positive direction.

The impurity concentration shown in FIG. 3 is the concentration of the second conductivity type impurity contained in JTE region 2, and is specifically an acceptor concentration. It is to be noted that the dose amount corresponds to an amount obtained by integrating the aforementioned impurity concentration with respect to the position in the Y direction.

In FIG. 3, the position in the Y direction of a peak concentration of the p type impurity is represented as a peak position P. Peak position P is a position on an inner side of JTE region 2 relative to the position 0. That is, according to the embodiment of the present invention, JTE region 2 has the peak concentration of the p type impurity at a position within silicon carbide layer 10 distant from first main surface 10a of silicon carbide layer 10. In this embodiment, the peak concentration is not less than 1×10¹⁶ cm⁻³ and not more than 5×10¹⁷ cm⁻³. Preferably, the peak concentration is not less than 1×10¹⁶ cm⁻³ and not more than 2×10¹⁷ cm⁻³. For example, in JTE region 2, the concentration of the p type impurity in the vicinity of first main surface 10a is approximately 1×10¹⁷ cm⁻³, while the concentration of the p type impurity at peak position P is approximately 2×10¹⁷ cm⁻³. Peak position P is a position within the range of not less than 0.3 μm and not more than 0.5 μm from the position 0 (first main surface 10a).

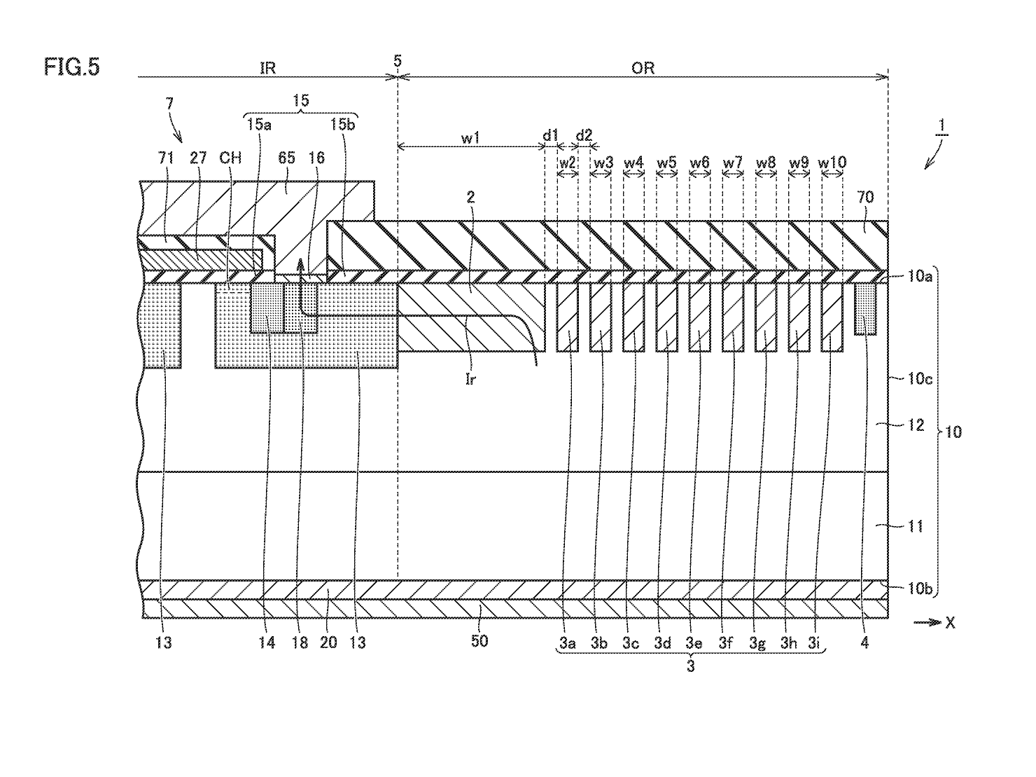

FIG. 5 is a schematic diagram showing the silicon carbide semiconductor device according to the embodiment of the present invention in which avalanche breakdown has occurred. Referring to FIG. 5, body region 13 and JTE region 2 are electrically connected together.

In this embodiment, silicon carbide semiconductor device 1 is an n channel type MOSFET. When silicon carbide semiconductor device 1 is used, drain voltage rises higher than source voltage. That is, when silicon carbide semiconductor device 1 is used under high voltage, the drain voltage rises higher than the source voltage.

The drain voltage is applied through backside surface protecting electrode 50 and drain electrode 20 to silicon carbide layer 10 (n⁺ substrate 11 and drift layer 12). The source voltage is applied through pad electrode 65 and source electrode 16 to source region 14 and p⁺ region 18. The source voltage is further applied through p⁺ region 18 to body region 13. JTE region 2 is electrically connected to body region 13. Accordingly, a depletion layer (not shown) extends from a junction surface between drift layer 12 and body region 13, drift layer 12, and a junction surface between drift layer 12 and JTE region 2.

Furthermore, a depletion layer extends from a junction surface between guard ring region 3 (each of guard ring portions 3a to 3i) and drift layer 12. For brevity of illustration, however, the depletion layer extending from the junction surface between drift layer 12 and JTE region 2 is described.

A JTE region 21 has the highest impurity concentration than in body region 13. As such, electric field concentration may occur in JTE region 2. For example, electric field tends to be concentrated at an end portion 21a of JTE region 21 due to a large curvature of a junction surface. Thus, avalanche breakdown may occur at the end portion of JTE region 2.

When avalanche breakdown occurs in JTE region 2, a reverse current Ir flows from drift layer 12 toward JTE region 2. Reverse current Ir flows from JTE region 2 to body region 13, and flows through p⁺ region 18 and source electrode 16 out to pad electrode 65.

It is considered that reverse current Ir tends to flow through a portion having a lower resistance value within JTE region 2. The portion having a lower resistance value corresponds to a portion having a higher p type impurity concentration. As shown in FIG. 3, a profile of the impurity concentration in the depth direction (Y direction) of JTE region 2 has a peak at a position distant from first main surface 10a of silicon carbide layer 10. It is thus considered that reverse current Ir tends to flow through the inside of JTE region 2, more specifically, a portion near the peak of the impurity concentration.

JTE region 2 and guard ring region 3 are in contact with first main surface 10a of silicon carbide layer 10. First main surface 10a corresponds to an interface between silicon carbide layer 10 and insulating film 15b. According to this embodiment, in JTE region 2 or guard ring region 3, reverse current Ir tends to flow through a portion distant from the interface between silicon carbide layer 10 and insulating film 15b. This can suppress degradation of insulating film 15b (oxide film). The life of silicon carbide semiconductor device 1 can be thus increased. Furthermore, the avalanche resistance of silicon carbide semiconductor device 1 can be increased.

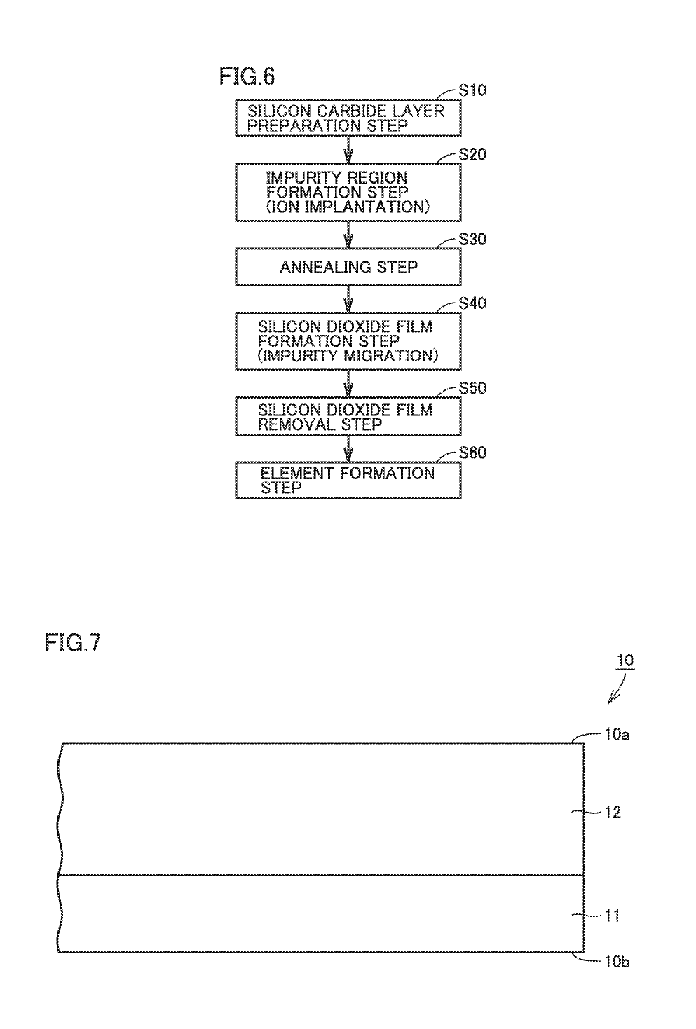

FIG. 6 is a flowchart schematically illustrating a method of manufacturing the silicon carbide semiconductor device according to one embodiment of the present invention. Referring to FIG. 6, first, silicon carbide layer 10 is prepared in a silicon carbide layer preparation step (S10). Referring to FIG. 7, drift layer 12 is formed by epitaxial growth on one main surface of n⁺ substrate 11 made of hexagonal silicon carbide having a polytype of 4H.

The epitaxial growth can be performed by employing, for example, a mixed gas of SiH₄ (silane) and C₃H₈ (propane) as a material gas. During the epitaxial growth, N (nitrogen), for example, is introduced as an n type impurity. Drift layer 12 containing a low concentration of an impurity than the impurity contained in n⁺ substrate 11 is thus formed. As a result of the silicon carbide layer preparation step (S10), silicon carbide layer 10 including first main surface 10a and second main surface 10b and having the first conductivity type (n type) is formed.

In this embodiment, drift layer 12 is formed on the c face of n⁺ substrate 11. The c face is defined herein as a surface having an off angle of not less than −8° and not more than 8° relative to (0001). By forming drift layer 12 on the c face, first main surface 10a of silicon carbide layer 10 serves as the c face, that is, a surface having an off angle of not less than −8° and not more than 8° relative to (0001). Next, an impurity region formation step (S20) shown in FIG. 6 is performed.

Although not shown in FIG. 7, an oxide film made of silicon dioxide is formed by CVD, for example, on first main surface 10a of silicon carbide layer 10. A resist is applied onto the oxide film, followed by exposure and development. A resist film having an opening in a region corresponding to the desired shape of body region 13 is thus formed. Then, the oxide film is partially removed by ME (Reactive Ion Etching), for example, with this resist film as a mask, to thereby form a mask layer formed of the oxide film having the opening pattern on first main surface 10a.

Referring to FIG. 8, ions of an impurity are implanted into first main surface 10a of silicon carbide layer 10. This forms body region 13, source region 14 and p⁺ region 18 in element region IR of silicon carbide layer 10, and forms JTE region 2 and guard ring region 3 serving as an electric field relaxing region in termination region OR of silicon carbide layer 10. It is to be noted that guard ring region 3 has the plurality of guard ring portions 3a to 3i.

Specifically, after the resist film described above is removed, ions of a p type impurity such as Al are implanted into drift layer 12 with the mask layer as a mask, to form body region 13. Ions of an n type impurity such as P (phosphorus) are introduced into body region 13 of drift layer 12, to form source region 14. Then, ions of a p type impurity such as Al, B are implanted into body region 13 of drift layer 12, to form p⁺ region 18. It is to be noted that the ion implantations may be performed while silicon carbide layer 10 is heated at a temperature of approximately between 300° C. and 500° C.

Furthermore, ions of a p type impurity such as Al are implanted into drift layer 12, to form JTE region 2 and guard ring region 3. JTE region 2 is formed to be in contact with body region 13. Furthermore, each of JTE region 2 and guard ring region 3 is formed to be in contact with first main surface 10a of silicon carbide layer 10.

Preferably, a dose amount of the p type impurity into JTE region 2 is not less than 1×10¹³ cm⁻². Preferably, the dose amount of the p type impurity into JTE region 2 is within the range of not less than 1×10¹³ cm⁻² and not more than 2×10¹³ cm⁻² (by way of example, 1.65×10¹³ cm⁻²). A dose amount of the implantation into guard ring region 3 is not less than 1×10¹³ cm⁻². As described above, the dose amount of the impurity contained in guard ring region 3 may be substantially equal to the dose amount of the impurity contained in JTE region 2 (for example, within the range of ±5% with reference to the dose amount of the impurity contained in JTE region 2).

Next, an activation annealing step (S30) is performed. In the step (S30), heat treatment is performed for activating the impurities introduced by the ion implantations. Specifically, silicon carbide layer 10 into which the ions have been implanted is heated to approximately 1700° C. in an Ar (argon) atmosphere, for example, and held for approximately 30 minutes.

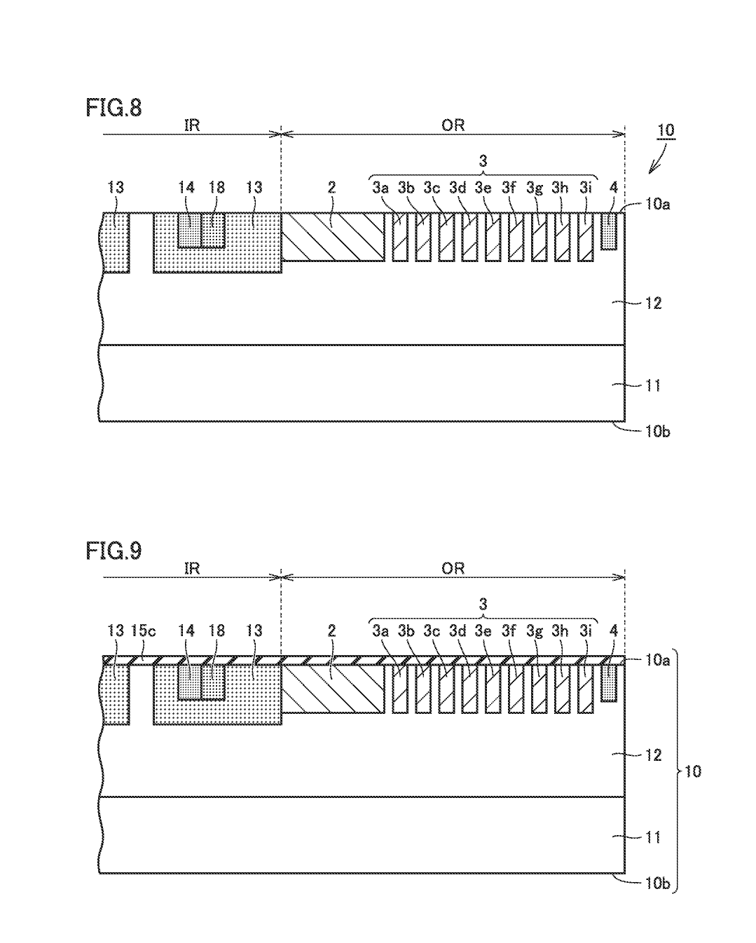

Referring to FIGS. 6 and 9, a silicon dioxide film formation step (S40) is performed. First main surface 10a of silicon carbide layer 10 in which the impurity regions have been formed is subjected to thermal oxidation. The thermal oxidation can be performed by maintaining a state, in which silicon carbide layer 10 is heated to between approximately 1100° C. and approximately 1300° C. in an atmosphere of oxygen-containing gas, for example, for approximately 40 minutes. A silicon dioxide film 15c is thus formed in contact with first main surface 10a of silicon carbide layer 10.

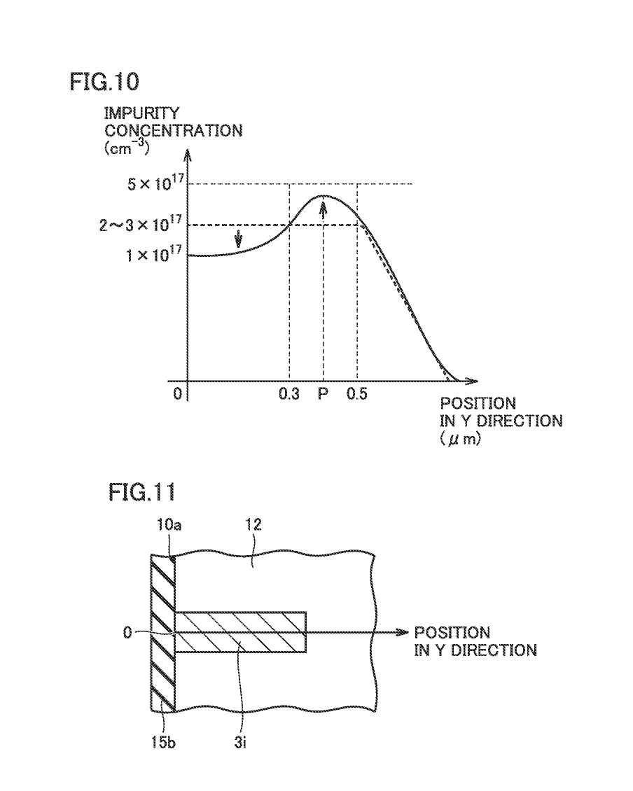

The thermal oxidation causes silicon in first main surface 10a of silicon carbide layer 10 to combine with oxygen, whereby silicon dioxide film 15c (thermal oxidation film) is formed. Carbon atoms arranged in the vicinity of first main surface 10a (c face), on the other hand, migrate (diffuse) into silicon carbide layer 10 with this thermal oxidation. This can lower the density of defects within silicon carbide layer 10. Furthermore, as shown in FIG. 10, the migration (rearrangement) of the carbon atoms from first main surface 10a into silicon carbide layer 10 can cause the p type impurity (aluminum (Al)) arranged in the vicinity of main surface 10a to migrate into silicon carbide layer 10. This lowers the concentration of the p type impurity in the vicinity of first main surface 10a. By the migration of the p type impurity in the vicinity of first main surface 10a into silicon carbide layer 10, the concentration of the p type impurity peaks within JTE region 2. Accordingly, JTE region 2 can have a concentration profile in which the impurity concentration peaks at a position (peak position P) within the range of not less than 0.3 μm and not more than 0.5 μm from the position 0 (first main surface 10a).

The peak concentration is not less than 1×10¹⁶ cm⁻³ and not more than 5×10¹⁷ cm⁻³. Before the silicon dioxide film formation step (S40), for example, the impurity concentration in the vicinity of main surface 10a is in the order of 10¹⁷ cm⁻³ (for example, between 2×10¹⁷ cm⁻³ and 3×10¹⁷ cm⁻³). By performing the step (S40), the concentration profile shown in FIG. 10 can be formed.

Next, an oxide film removal step (S50) shown in FIG. 6 is performed. Specifically, silicon dioxide film 15c (thermal oxidation film) shown in FIG. 10 is removed by a wet etching process with hydrofluoric acid. Thus, the step (S40) can be regarded as a sacrificial oxidation step.

Next, an element formation step (S60) shown in FIG. 6 is performed. Referring to FIGS. 1 and 6, gate electrode 27 made of a conductor such as polysilicon, aluminum is formed in contact with insulating film 15 to extend from above one of source regions 14 to above the other source region 14. When polysilicon is employed as a material for gate electrode 27, the polysilicon may contain phosphorus at a high concentration of more than 1×10²⁰ cm⁻³. Then, interlayer insulating film 71 made of silicon dioxide, for example, is formed to cover gate electrode 27.

Next, an electrode formation step is performed. Source electrode 16 made of a material including nickel and silicon, for example, is formed in contact with source region 14 and p⁺ region 18. Source electrode 16 may be made of a material including titanium, aluminum and silicon. By heating silicon carbide layer 10 on which source electrode 16 has been formed to approximately 1000° C., source electrode 16 is silicided, whereby source electrode 16 in ohmic contact with source region 14 and p⁺ region 18 of silicon carbide layer 10 is formed. Likewise, drain electrode 20 in ohmic contact with second main surface 10b of silicon carbide layer 10 is formed. Drain electrode 20 may be made of a material including nickel and silicon, or a material including titanium, aluminum and silicon. Pad electrode 65 which is in contact with source electrode 16 and made of aluminum, for example, is formed. In addition, backside surface protecting electrode 50 including titanium, nickel and silver, for example, is formed. By performing the above steps, silicon carbide semiconductor device 1 (MOSFET) shown in FIG. 1 is completed.

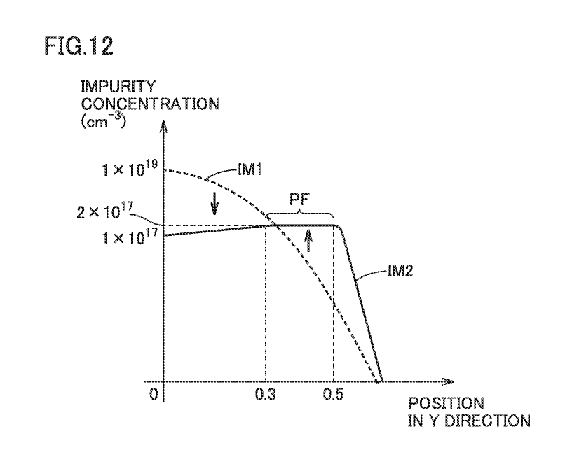

Moreover, guard ring region 3 (each of guard ring portions 3a to 3i) can also have the concentration profile shown in FIG. 3 or 10. A Y direction shown in FIG. 11 is the direction of the normal to first main surface 10a of silicon carbide layer 10, and corresponds to the Y direction shown in FIG. 4. That is, an impurity region having the concentration profile shown in FIGS. 3 and 10 can include one or both of JTE region 2 and guard ring region 3.

As described above, according to the first embodiment, silicon carbide semiconductor device 1 includes the impurity region having the peak concentration of the p type impurity within silicon carbide layer 10 distant from first main surface 10a of silicon carbide layer 10. This impurity region can include one or both of JTE region 2 and guard ring region 3. The avalanche resistance of silicon carbide semiconductor device 1 can be thus increased. In addition, the life of silicon carbide semiconductor device 1 can be increased.

### Second Embodiment

The configuration of a silicon carbide semiconductor device according to a second embodiment is similar to the configuration shown in FIGS. 1 and 2. Moreover, a method of manufacturing the silicon carbide semiconductor device according to the second embodiment is similar to the manufacturing method described with reference to FIGS. 3 to 9. The second embodiment is different from the first embodiment in terms of the concentration profile of the p type impurity in one or both of JTE region 2 and guard ring region 3.

FIG. 12 is a schematic diagram of a concentration profile in the p type impurity concentration region in the second embodiment of the present invention. Referring to FIGS. 6 and 12, in the second embodiment, the impurity region formation step (S20) includes a step of implanting ions of the p type impurity (for example, aluminum (Al)) such that the concentration of the p type impurity decreases as the depth from first main surface 10a of silicon carbide layer 10 increases. That “the depth from first main surface 10a of silicon carbide layer 10 increases” means that a value indicating the position in the Y direction increases. For example, as indicated by a concentration profile IM1 (broken-line curve), the p type impurity concentration at the position of first main surface 10a (position 0) is approximately 1×10¹⁹ cm⁻³.

Thereafter, the activation annealing step (S30), and then the silicon dioxide film formation step (S40) are performed. As in the first embodiment, in the step (S40), the concentration of the p type impurity in the vicinity of main surface 10a is lowered by causing the p type impurity (aluminum (Al)) arranged in the vicinity of main surface 10a to migrate into silicon carbide layer 10. As a result, in JTE region 2, the impurity concentration peaks at a position within the range of not less than 0.3 μm and not more than 0.5 μm from the position 0 (first main surface 10a).

In contrast to the first embodiment, in the second embodiment, a concentration profile IM2 is formed as a result of the step (S40), which includes a portion PF where the concentration of the p type impurity flattens out with respect to the depth direction from first main surface 10a of silicon carbide layer 10. Flat portion PF is the portion of a flat peak of the impurity concentration, which is present within the range of between 0.3 μm and 0.5 μm of the position in the Y direction. Thus, the impurity concentration in portion PF is within the range of not less than 1×10¹⁶ cm⁻³ and not more than 5×10¹⁷ cm⁻³.

The term “flat” means that the impurity concentration can be considered as substantially not varying with respect to variation in the position in the Y direction. For example, as the position in the Y direction varies from 0 μm to 0.3 μm, the concentration of the p type impurity varies from approximately 1×10¹⁷ cm⁻³ to approximately 2×10¹⁷ cm⁻³. In contrast, as the position in the Y direction varies from 0.3 μm to 0.5 μm, the concentration of the p type impurity varies from approximately 2×10¹⁷ cm⁻³ to approximately 1×10¹⁶ cm⁻³. When the variation in the concentration of the p type impurity as the position in the Y direction varies from 0.3 μm to 0.5 μm is an order of magnitude smaller than the variation in the concentration of the p type impurity as the position in the Y direction varies from 0 μm to 0.3 μm as in this example, the impurity region (for example, JTE region 2) can be considered as having a concentration profile in which the p type impurity concentration flattens out.

According to the second embodiment, as in the first embodiment, one or both of JTE region 2 and guard ring region 3 can be an impurity region having a peak concentration of the p type impurity within silicon carbide layer 10 distant from first main surface 10a of silicon carbide layer 10. The avalanche resistance of silicon carbide semiconductor device 1 can be thus increased. Furthermore, the life of silicon carbide semiconductor device 1 can be increased.

Particularly, in the second embodiment, within silicon carbide layer 10 distant from first main surface 10a of silicon carbide layer 10, the impurity concentration profile in the impurity region (one or both of JTE region 2 and guard ring region 3) has a flat portion. Accordingly, when avalanche breakdown occurs, a portion through which reverse current Ir (see FIG. 5) flows (current path) increases in width in the depth direction. In other words, when reverse current Ir flows through JTE region 2 and/or guard ring region 3, the current density in that region can be lowered. This can further improve the breakdown resistance of silicon carbide semiconductor device 1. Furthermore, the life of silicon carbide semiconductor device 1 can be further increased. It is to be noted that the MOSFET shown in FIG. 1 is a planar MOSFET.

However, the MOSFET implemented as the embodiment of the present invention may be a trench MOSFET. Furthermore, although a MOSFET has been described by way of example as the silicon carbide semiconductor device in the above embodiments, the silicon carbide semiconductor device may be a diode such as a Schottky barrier diode, or an IGBT (Insulated Gate Bipolar Transistor).

The first conductivity type is n type and the second conductivity type is p type in the above embodiments. This can improve the manufacturability of the silicon carbide semiconductor device. However, the first conductivity type may be p type and the second conductivity type is n type.

It should be understood that the embodiments disclosed herein are illustrative and non-restrictive in every respect. The scope of the present invention is defined by the terms of the claims, rather than the embodiments described above, and is intended to include any modifications within the scope and meaning equivalent to the terms of the claims.

### REFERENCE SIGNS LIST

1 silicon carbide semiconductor device; 2 JTE region; 3 guard ring region; 3a to 3i guard ring portion; 4 field stop region; 5 boundary; 7 semiconductor element portion; 10 silicon carbide layer; 10a first main surface; 10b second main surface; 10c end (silicon carbide layer); 11 n⁺ substrate; 12 drift layer; 13 body region; 14 source region; 15, 15b, 70 insulating film; 15a gate insulating film; 15c silicon dioxide film; 16 source electrode; 18 p⁺ region; 20 drain electrode; 27 gate electrode; 50 backside surface protecting electrode; 65 pad electrode; 71 interlayer insulating film; CH channel region; IM1 concentration profile; IR element region; Ir reverse current; OR termination region; P peak position; PF flat portion; X direction; d1, d2 distance; w1 to w0 width.

1. A silicon carbide semiconductor device comprising:
a silicon carbide layer including a first main surface and a second main surface located opposite the first main surface, and having a first conductivity type;
an element region including a semiconductor element portion formed in the silicon carbide layer; and
an impurity region having a second conductivity type different from the first conductivity type, and being disposed within the silicon carbide layer to surround the element region as seen in plan view,
the impurity region having a peak concentration of an impurity of the second conductivity type at a position within the silicon carbide layer distant from the first main surface of the silicon carbide layer,
the peak concentration being not less than 1×10¹⁶ cm⁻³ and not more than 5×10¹⁷ cm⁻³.

2. The silicon carbide semiconductor device according to claim 1, wherein
the position of the peak concentration is a position of not less than 0.3 μm and not more than 0.5 μm from the first main surface of the silicon carbide layer.

3. The silicon carbide semiconductor device according to claim 1, wherein
the impurity region is disposed within the silicon carbide layer to be in contact with the first main surface of the silicon carbide layer.

4. The silicon carbide semiconductor device according to claim 1, wherein
the impurity region includes a JTE (Junction Termination Extension) region.

5. The silicon carbide semiconductor device according to claim 1, wherein
the impurity region includes a guard ring region.

6. The silicon carbide semiconductor device according to claim 1, wherein
the first main surface of the silicon carbide layer is a surface having an off angle of not less than −8° and not more than 8° relative to a (0001) plane.

7. The silicon carbide semiconductor device according to claim 1, wherein
the first conductivity type is n type, and
the second conductivity type is p type.

8. A method of manufacturing a silicon carbide semiconductor device, comprising the steps of:
preparing a silicon carbide layer including a first main surface and a second main surface located opposite the first main surface, and having a first conductivity type;
forming an impurity region including an impurity having a second conductivity type different from the first conductivity type within the silicon carbide layer, by implanting ions of the impurity into a region of the silicon carbide layer that surrounds an element region where a semiconductor element portion is to be disposed;
activating the impurity by heating the silicon carbide layer; and
forming a silicon dioxide film to cover the first main surface of the silicon carbide layer by performing thermal oxidation on the silicon carbide layer,
the step of forming a silicon dioxide film including the step of lowering a concentration of the impurity in the vicinity of the first main surface, by causing the impurity to migrate from the first main surface of the silicon carbide layer into the silicon carbide layer.

9. The method of manufacturing a silicon carbide semiconductor device according to claim 8, wherein
by the step of forming a silicon dioxide film, the impurity region has a peak concentration of the impurity at a position within the silicon carbide layer distant from the first main surface, and
the peak concentration is not less than 1×10¹⁶ cm⁻³ and not more than 5×10¹⁷ cm⁻³.

10. The method of manufacturing a silicon carbide semiconductor device according to claim 9, wherein
the position of the peak concentration is a position of not less than 0.3 μm and not more than 0.5 μm from the first main surface of the silicon carbide layer.

11. The method of manufacturing a silicon carbide semiconductor device according to claim 8, wherein
the impurity region is disposed within the silicon carbide layer to be in contact with the first main surface of the silicon carbide layer.

12. The method of manufacturing a silicon carbide semiconductor device according to claim 8, wherein
the impurity region includes a JTE (Junction Termination Extension) region.

13. The method of manufacturing a silicon carbide semiconductor device according to claim 8, wherein
the impurity region includes a guard ring region.

14. The method of manufacturing a silicon carbide semiconductor device according to claim 8, wherein
the first main surface of the silicon carbide layer is a surface having an off angle of not less than −8° and not more than 8° relative to a (0001) plane.

15. The method of manufacturing a silicon carbide semiconductor device according to claim 8, wherein
the step of forming an impurity region includes the step of implanting the ions of the impurity such that the concentration of the impurity decreases as a depth from the first main surface of the silicon carbide layer increases, and
the step of forming a silicon dioxide film includes the step of forming a concentration profile of the impurity, the concentration profile including a portion where the concentration of the impurity flattens out with respect to a depth direction from the first main surface of the silicon carbide layer.

16. The method of manufacturing a silicon carbide semiconductor device according to claim 8, wherein
the first conductivity type is n type, and
the second conductivity type is p type.
